(19) United States
(12) Patent Application Publication
(10) Pub. No.: US 2007/0018230 A1
(43) Pub. Date: Jan. 25, 2007

(54) Eeprom and methods of fabricating the same

(75) Inventors: Weon-Ho Park, Suwon-si (KR); Byoung-Ho Kim, Suwon-si (KR); Sang-Woo Kang, Seoul (KR); Jeong-Uk Han, Suwon-si (KR); Sung-Woo Park, Gunpo-si (KR)

Correspondence Address: MILLS & ONELLO LLP, ELEVEN BEACON STREET, SUITE 605, BOSTON, MA, 02108, US

(73) Assignee: Samsung Electronics Co.,Ltd.

(21) Appl. No.: 11/490,768

(22) Filed: Jul. 21, 2006

(30) Foreign Application Priority Data
Jul. 22, 2005 (KR) 10-2005-0066883
Dec. 19, 2005 (KR) 10-2005-0125499

(51) Int. Cl. H01L 29/788

(52) U.S. Cl. 257/315

(57) ABSTRACT

An EEPROM includes a tunneling opening having an inclined or a stepped sidewall. A tunnel insulation layer is formed within the tunneling opening. Using a flowed photoresist pattern as an etching mask, the gate insulator is etched to form a tunneling opening having an inclined sidewall. Thus, the tunnel insulation layer can be formed in a smaller area than an area defined by a photolithography. As a result, a width of an active region and a width of a wordline are decreased to reduce a unit cell size.

### CROSS-REFERENCE TO RELATED PATENT APPLICATION

This application claims priority to Korean Patent Application No. 10-2005-0066883, filed on Jul. 22, 2005 in the Korean Intellectual Property Office, and Korean Patent Application No. 10-2005-0125499, filed on Dec. 19, 2005 in the Korean Intellectual Property Office, the contents of which are incorporated herein in their entirety by reference.

### BACKGROUND OF THE INVENTION

The present invention relates to a semiconductor and a method of fabricating the same. More specifically, the present invention is directed to an electrically erasable programmable read only memory (EEPROM) capable of electrically storing and erasing data, and methods of fabricating the same.

Generally, a memory cell of an EEPROM includes a memory transistor of a floating gate tunnel oxide (FLOTOX) structure and a selection transistor for selecting the memory transistor.

The memory transistor of the FLOTOX structure has a structure in which an insulated floating gate is formed between a gate electrode and an active region. The floating gate is insulated from the active region through a tunnel insulating layer and the control gate electrode through an integrated dielectric layer. As compared to the memory transistor, the selection transistor can have a conventional metal oxide semiconductor (MOS) transistor structure. In a fabricating process, the selection transistor can have a stacked gate structure. A top gate pattern and a bottom gate pattern of the stacked gate structure of the selection transistor can be connected to each other in an arbitrary portion of a substrate.

FIG. 1 is a plan view and FIG. 2 is a sectional view of a conventional EEPROM.

Referring to FIG. 1 and FIG. 2, a gate insulator 14 is formed on a substrate 10 on which a device isolation layer 12 defining an active region is formed. The gate insulator 14 is formed on the active region, and a tunnel insulation layer 14t thinner than the gate insulator 14 is formed on a portion of the active region.

A sensing line SL is formed on the tunnel insulation layer 14t and the gate insulator 14 and crosses over the active region. A wordline WL is formed spaced apart from the sensing line SL and crosses over the active region.

A source region 26s, a drain region 26d, and a floating diffusion region 26f are formed in the active region of the substrate 10. The sensing lines SL are formed on the active region between the source region 26s and the floating diffusion region 26f. Additionally, the sensing line SL is formed on a portion of the gate insulator 14 that includes the tunnel insulation layer 14t and, thus, on a portion of the floating diffusion region 26f.

The wordline WL is formed on a portion of the active region between the floating diffusion region 26f and the drain region 26d. The wordline WL includes a bottom wordline 22w and a top wordline 24w, which is stacked on the bottom wordline 22w. The bottom wordline 22w and the top wordline 24w are electrically connected to each other on an arbitrary portion of the substrate 10. The sensing line SL includes a floating gate 22s restrictively formed on a portion of the active region and a control gate electrode 24s formed on the floating gate 22s and crossing over the active region.

An interlayer insulation layer 28 is formed on the sensing line SL and the wordline WL, and exposed portions of the gate insulator 14. Additionally, a bitline BL is formed on the interlayer insulation layer 28 and a bitline contact 30 electrically connects the bitline BL to the drain region 26d, through the interlayer insulation layer 28.

The EEPROM using tunneling of charge by a vertical electric field formed on the tunnel insulation layer 14t injects the charge into the floating gate 22s, or writes or erases information through discharging the charge of the floating gate 22s into the floating diffusion region 26f. Accordingly, the electrical characteristic and the surface properties of the tunnel insulation layer 14t are important in the EEPROM. When the electrical characteristic of the tunnel insulation layer 14t is weak, unwanted leakage of the charge occurs through the tunnel insulation layer to lose the stored information. Also, trap density increases when the surface properties are weak, reducing the lifetime of a write-erase cycle.

FIG. 3 and FIG. 4 are sectional views illustrating a conventional method of fabricating an EEPROM, such as that in FIG. 1 and FIG. 2.

Referring to FIG. 3, the gate insulator 14 is formed on the semiconductor substrate 10 on which a device isolation layer defining an active region is formed. The gate insulator of a thermal oxide layer can be formed on the active region. A first photoresist pattern 16 is formed, which includes a first opening 16a exposing a portion of the active region on the substrate where the gate insulator 14 is formed. Using the first photoresist pattern 16 as an ion injection mask, a cell diffusion region 18 is formed by injecting impurities into the semiconductor substrate 10.

Referring to FIG. 4, the first photoresist pattern 16 is removed, and a second photoresist pattern 20 is formed on the semiconductor substrate, which includes a second opening 20a smaller than the first opening 16a. The second photoresist pattern 20 defines a region on which a tunnel insulation layer (e.g., 14t from FIGS. 1 and 2) is to be formed. Using the second photoresist pattern 20 as an etching mask, the gate insulator 14 is etched to form a tunneling opening 22, where the active region is exposed. When a plasma anisotropic etching is conducted to form the gate insulator 14, the tunnel opening 22 aligned on the second opening 20a can be formed. In this method, it is advantageous that the tunneling opening 22 be formed to have the minimum size defined by a photolithography. However, the plasma anisotropic etching causes a surface defect by damaging the surface of the substrate 10 exposed to the tunneling opening 22. As a result, the surface properties of the tunnel insulation layer (once formed) are degraded due to the surface defect of the substrate, i.e., to create or increase a leakage path and a trap site of the charge. Accordingly, the tunneling opening 22 is formed by etching the gate insulator 14 through an isotropic wet etching in the EEPROM fabricating process. When the tunneling opening 22 is formed using the isotropic wet etching, the gate insulator 14 is undercut into the second photoresist pattern 20 around the second opening 20a. Accordingly, the size W2 of the tunneling opening 22 is larger than the minimum size W1 of the second opening defined by the photolithography.

As capacity of the EEPROM increases, the size of the unit cell is reduced. Accordingly, there is a need to reduce the region on which the tunnel insulation layer is formed. When the tunneling opening 22 is formed using the isotropic wet etching, the size of the tunnel insulation layer is larger than the minimum size of the photolithography. Therefore, reduction of the unit cell size is limited.

### SUMMARY OF THE INVENTION

The present invention relates to electrically erasable programmable read only memory (EEPROM) capable of electrically storing and erasing data.

In accordance with one aspect of the present invention, provided is an EEPROM having: a semiconductor substrate where a device isolation layer is formed to define an active region; a gate insulator disposed on the active region and defining a tunneling opening exposing a portion of the active region; a tunnel insulation layer disposed on a portion of the active region exposed by the tunneling opening; a sensing line disposed on a first portion of the gate insulator and on the tunnel insulation layer, and on a first portion of the active region; and a wordline disposed on a second portion of the gate insulator and on a second portion of the active region, and spaced apart from the sensing line, wherein the gate insulator includes a side defining at least a portion of the tunneling opening and the side is inclined to make a bottom width of the tunneling opening smaller than a top width thereof.

The EEPROM can comprise a source region, a floating diffusion region, and a drain region formed in the active region, wherein the wordline can be disposed on the active region between the floating diffusion region and the drain region, and the sensing line can be disposed on the active region between the source region and the floating diffusion region. The tunnel insulation layer can be disposed on the floating diffusion region.

The sensing line can comprise a floating gate disposed on a first portion of the active region and a control gate electrode disposed on, and insulated from, the floating gate. The wordline can comprise a bottom wordline disposed on a second portion of the active region and a top wordline disposed on the bottom wordline, wherein the bottom and top wordlines are electrically connected to each other. The EEPROM can comprise a tunnel diffusion layer disposed in the active region and below the tunnel insulation layer.

In accordance with another aspect of the present invention, provided is a method of fabricating an EEPROM. The method can include: forming a gate insulator on an active region of a semiconductor substrate having a device isolation layer formed therein to define the active region; forming a first photoresist pattern having a first opening exposing a first injection portion of the gate insulator; injecting impurities into the gate insulator using the first photoresist pattern as an ion injection mask; isotropically etching the gate insulator using the first photoresist pattern as an etching mask to form a tunneling opening having a stepped side; removing the first photoresist pattern; forming a tunnel insulation layer on a portion of the active region exposed by the tunneling opening; and forming a sensing line on the tunnel insulation layer, on a first portion of the gate insulator, and on a first portion of the active region and forming a wordline on a second portion of the gate insulator and on a second portion of the active region, wherein the wordline is spaced apart from the sensing line.

The method can comprise, before injecting the impurities, flowing the first photoresist pattern to reduce a width of the first opening. Forming the tunneling opening can include performing an isotropic wet etching of the gate insulator.

The method can further comprise forming a second photoresist pattern having a second opening exposing a second injection portion of the gate insulator and the tunneling opening; injecting impurities into the active region using the second photoresist pattern as an ion injection mask; and removing the second photoresist pattern. Forming the tunnel insulation layer can be done after removing the second photoresist pattern.

The method can further comprise injecting impurities into the active region using the wordline and the sensing line as an ion injection mask to form a source region, a floating diffusion region, and a drain region.

In yet another aspect of the invention, provided is a method of fabricating an EEPROM. The method includes: sequentially forming a gate insulator, a hard mask layer, and anti-reflective film on an active region of a semiconductor substrate having a device isolation layer formed therein to define the active region; forming a first photoresist pattern having a first opening exposing a portion of the anti-reflective film; reflowing the first photoresist pattern to reduce a width of the first opening; etching the anti-reflective film and the hard mask layer using the first photoresist pattern as an etching mask to form a second opening exposing the gate insulator; removing the first photoresist pattern; etching the gate insulator using the hard mask layer as an etching mask to form a tunneling opening; removing the hard mask layer and the anti-reflective film; and forming a tunnel insulation layer at the tunneling opening.

The method can further comprise injecting impurities through the gate insulator exposed by the second opening.

In the method, forming the tunneling opening can include: etching a first portion of the gate insulator having been injected with the impurities at a first etch rate; and etching other portions of the gate insulator covered with the hard mask at a second, slower etch rate.

Etching the gate insulator can include isotropic wet etching to form the tunneling opening.

The anti-reflective film can be an organic anti-reflective film that is removed with the photoresist pattern. If the anti-reflective film is an inorganic anti-reflective film, the anti-reflective film can be removed after forming the tunneling opening and before removing the hard mask.

The method can further comprise forming a sensing line on the tunneling insulation layer and on a first portion of the gate insulator, and on a first portion of the active region, and forming a wordline on a second portion of the active region and spaced apart from the sensing line.

The method can further comprise injecting impurities into the active region using the wordline and the sensing line as an ion injection mask to form a source region, a floating diffusion region, and a drain region.

In accordance with yet other aspects of the invention, provided is a method of fabricating an EEPROM. The method includes: forming a gate insulator on an active region of a semiconductor substrate having a device isolation layer formed therein to define the active region; forming a first photoresist pattern having a first opening exposing a first injection portion of the gate insulator; injecting impurities into the gate insulator using the first photoresist pattern as an ion injection mask; isotropically etching the gate insulator using the first photoresist pattern as an etching mask to form a tunneling opening; removing the first photoresist pattern; and forming a tunnel insulation layer on a portion of the active region exposed by the tunneling opening, wherein the tunnel insulation layer covers an area not greater than that of the first opening.

The method can further comprise forming a sensing line on the tunnel insulation layer, on a first portion of the gate insulator, and on a first portion of the active region and forming a wordline on a second portion of the gate insulator and on a second portion of the active region, wherein the wordline is spaced apart from the sensing line.

### BRIEF DESCRIPTION OF THE DRAWINGS

FIG. 1 is a plan view of a conventional EEPROM.

FIG. 2 is a sectional view taken along a line I-I′ of FIG. 1.

FIG. 3 and FIG. 4 are sectional views of a conventional method of fabricating an EEPROM.

FIG. 5 through FIG. 9 are sectional views illustrating an EEPROM and a method of fabricating the same according to an embodiment of various aspects of the present invention.

FIG. 10 through FIG. 14 are sectional views illustrating a method of fabricating an EEPROM according to another embodiment of aspects of the present invention.

### DETAILED DESCRIPTION OF THE INVENTION

Embodiments of various aspects of the invention are described below with reference to the accompanying drawings. This invention can, however, be embodied in many different forms and should not be construed as limited to the embodiments set forth herein. Rather, these embodiments are provided so that this disclosure will be thorough, and will convey various aspects of the invention to those skilled in the art. In the drawings, the thickness or other dimensions of films, layers, substrates, patterns and regions are exaggerated for clarity, and should not be construed as limitations. It will also be understood that when a film, substrate, layer or pattern is referred to as being “on” another film, substrate, layer or pattern it can be directly on the other film, substrate, layer or pattern, or intervening films or substrates, layers or patterns can also be present. Similarly, with respect to the invention and embodiments herein, when two or more items are referred to as being “connected” or “coupled” they could be directly connected or coupled, or there could be intervening items between the connected or coupled items. Like reference numerals in the drawings denote like elements.

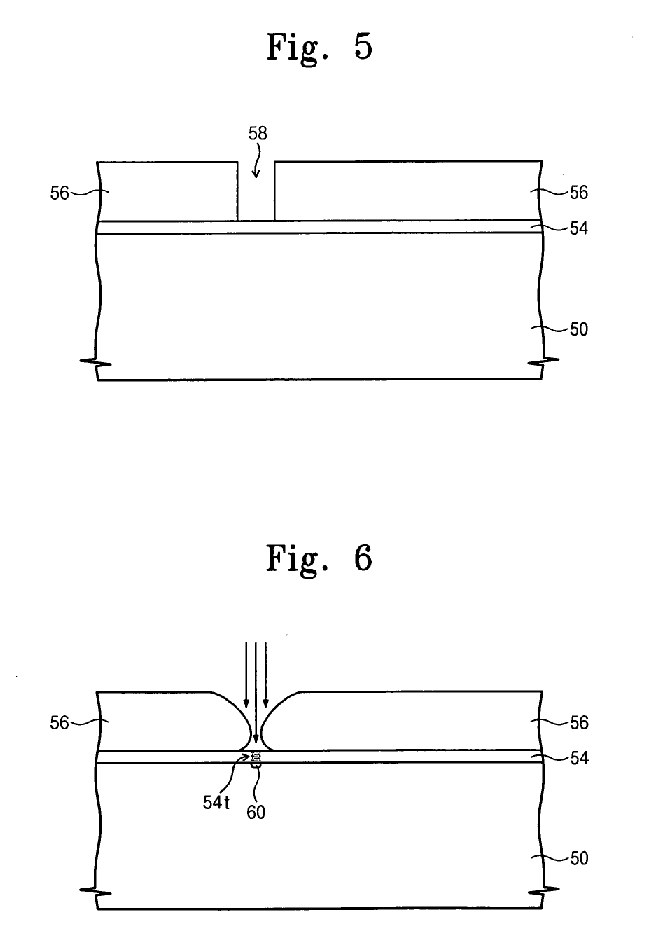

FIG. 5 through FIG. 9 are sectional views illustrating an electrically erasable programmable read only memory (EEPROM) and a method of fabricating the same according to an embodiment of the present invention.

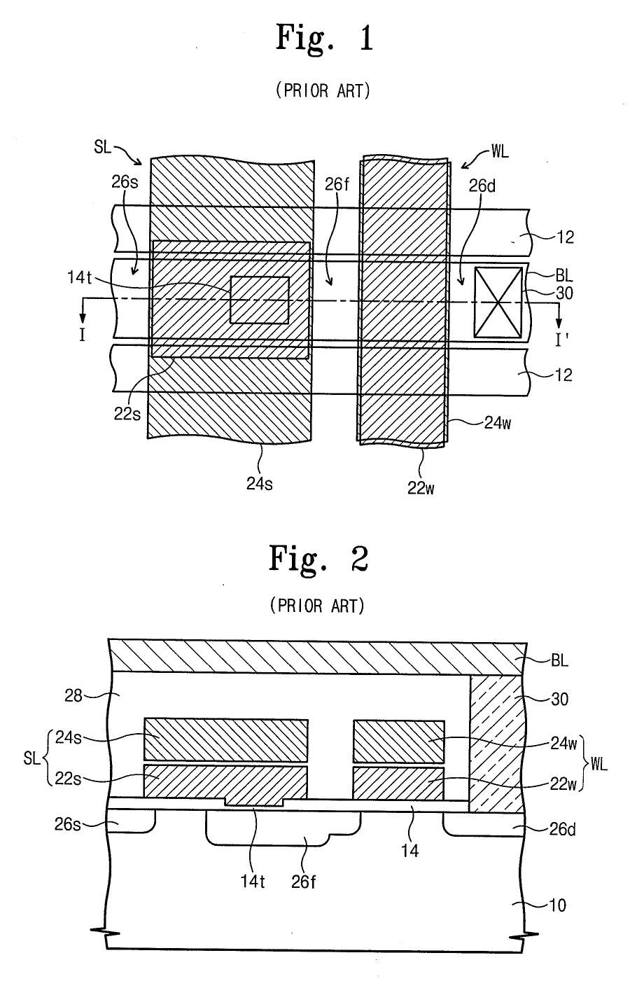

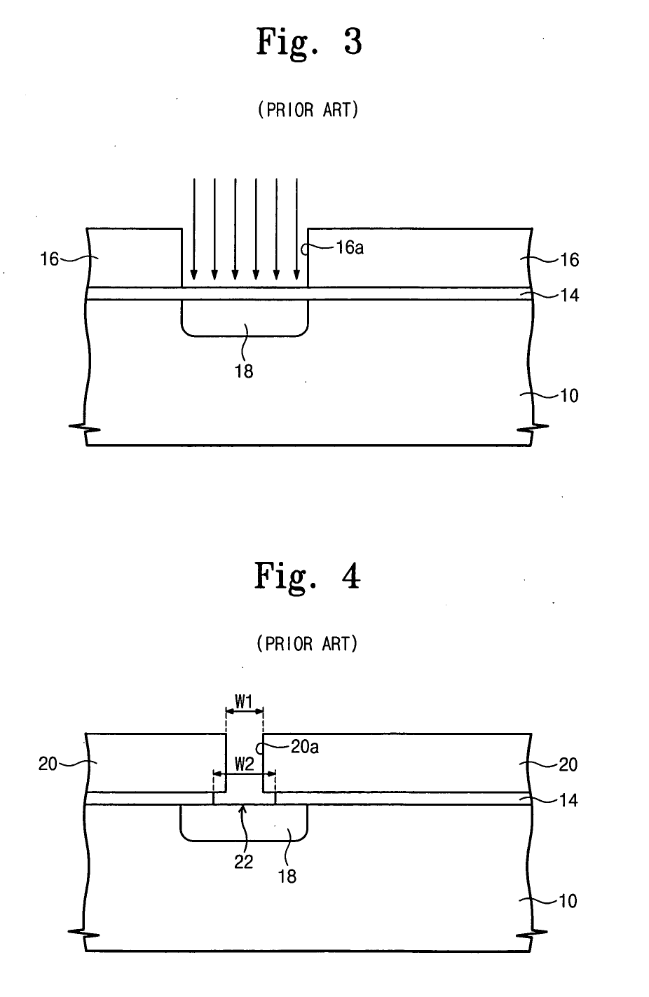

Referring to FIG. 5, a device isolation layer (not shown) is conventionally formed on a semiconductor substrate 50 to define an active region, similar to the formation of device isolation layer 12 in FIG. 1. A gate insulator 54 is formed on a semiconductor substrate 50 where the active region is defined. The gate insulator 54 can be deposited through a chemical vapor deposition (CVD) process and can be made of thermal oxide formed on the active region. A first photoresist pattern 56 is formed on a substrate where the gate insulator is formed. The first photoresist pattern 56 includes a first opening 58 through which the tunnel insulation layer is to be formed. The first opening 58 can be formed in the minimum size defined by a photolithography.

Referring to FIG. 6, to reduce an active region exposed to the first opening 58 when viewed from a top surface of the first photoresist 56, a photoresist can be flowed by annealing the substrate 50 where the first photoresist pattern 56 is formed. Using the first photoresist 56 as an ion injection mask, impurities are injected into the gate insulator 54 and the active region. As a result, an ion injection damage layer 54t is formed in the gate insulating layer 54 and a tunnel diffusion layer 60 is formed on the active region. The gate insulator 54 has different etching speeds, one in the region exposed to ions and the other in the regions not exposed to ions.

Referring to FIG. 7, using the first photoresist pattern 56 as an etching mask, the gate insulator 54 is etched to form a tunneling opening 54a where the active region is exposed.

When an anisotropic dry etch is conducted for the gate insulator 54, the active region exposed to the tunneling opening can be damaged. Thus, it is desirable that the isotropic wet etching is performed on the gate insulator 54 to prevent the etching damage. According to an etching speed of the gate insulator 54 in the region 54t (see FIG. 6) exposed to ions and in other regions not exposed to ions, a portion, on which the tunnel diffusion layer 60 is formed, is rapidly etched and the active region is exposed. Peripheral portions of the gate insulator 54 have slower etching speeds and, therefore, the active region is not exposed at these portions. Consequently, the tunneling opening 54a is defined by sides of the gate insulator 54 in the form of a step or an inclined sidewall.

Thus, although the ion injection damage layer 54t is not formed in the gate insulator 54, the tunneling opening 54a can be formed in a size smaller than the size defined by a photolithography when the gate insulator 54 is etched using the first photoresist 56 as an etching mask.

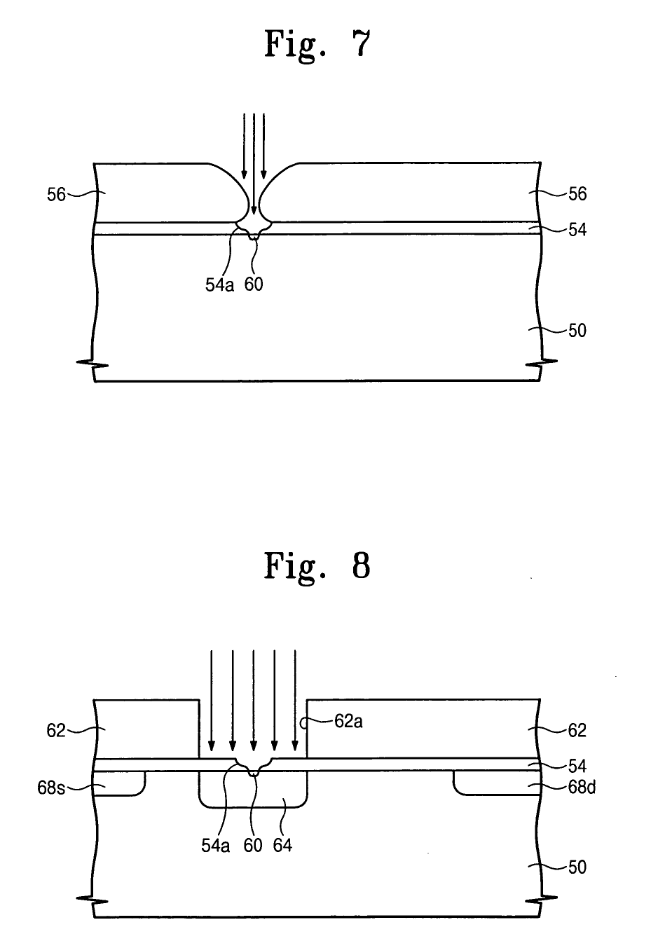

Referring to FIG. 8, the first photoresist pattern 56 is removed and a second photoresist pattern 62 is formed. The second photoresist pattern 62 includes a second opening 62a defining the cell diffusion region. The region on which the tunneling opening 54a is formed is exposed by the second opening 62a. Using the second photoresist pattern 62 as an ion injection mask, impurities are injected into the active region, and the cell diffusion region 64 is formed.

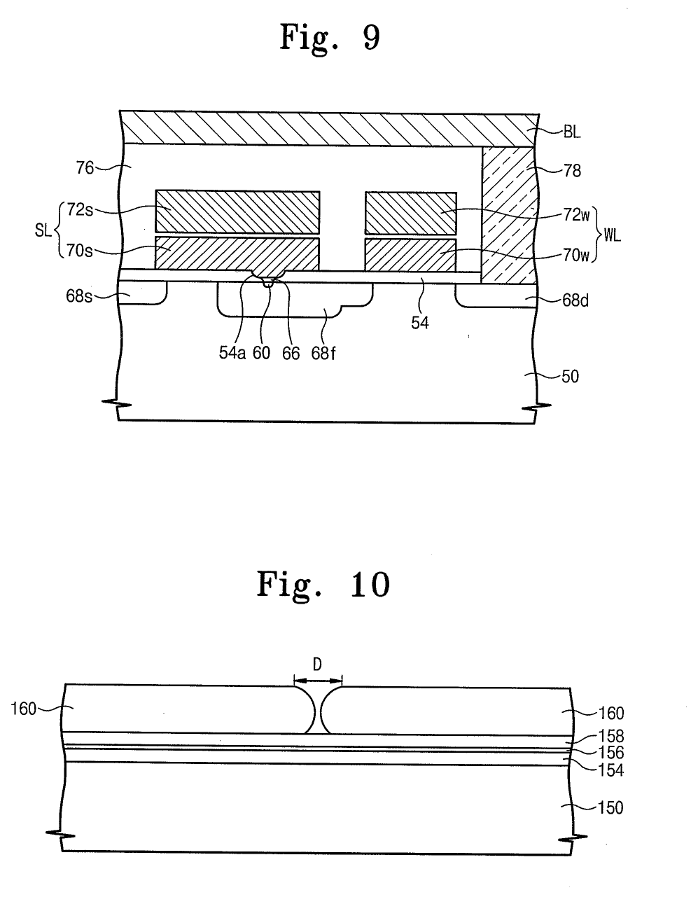

Referring to FIG. 9, the gate insulator 54 with the tunneling opening 54a is exposed by removing the second photoresist pattern 62. In the tunneling opening 54a, the active region of a size smaller than the size defined by a photolithography is exposed. The tunnel insulation layer 66 is formed on the active region exposed to the tunneling opening 54a. The tunnel insulation layer 66 can remedy surface defects of the substrate. The tunnel insulation layer 66 can be formed of a thermal oxide layer having excellent electrical characteristics.

Next, a sensing line SL and a wordline WL are conventionally formed to cross over the active region. The sensing line SL includes a floating gate 70s that covers the tunnel insulation layer 66 and overlaps a portion of the cell diffusion region 64. The sensing line SL also includes a control gate electrode 72s that crosses over the active region and is insulated from the floating gate 70s through a gate interlayer dielectric (not shown). The wordline WL includes a bottom wordline 70w that crosses over the active region and a top wordline 72w. The wordline WL can be formed according to a well-known fabricating process. Like the floating gate 70s and the control gate electrode 72s, the bottom wordline 70w and the top wordline 72w can be insulated by the gate interlayer dielectric (not shown). To electrically connect the bottom wordline 70w with the top wordline 72w, a contact pattern can be formed by forming an opening in the gate interlayer dielectric or applying a butting contact process after forming the wordline WL.

Using the sensing line SL and the wordline WL as an ion injection mask, impurities can be injected into the active region. Thus, a source region 68s and a drain region 68d can be formed in the active region and adjacent to the sensing line SL and the wordline WL. And a floating diffusion region 68f connected to the cell diffusion region can be formed in the active region between the sensing line SL and the wordline WL.

An interlayer dielectric 76 is formed on the substrate, including the sensing line and word line. A contact hole is formed within the interlayer dielectric to expose at least a portion of the drain region 68d A bitline contact 78 is formed, which is connected to the drain region 68d by filling the contact hole with the conductive material. A conductive layer is formed on the interlayer dielectric 76, including a bitline BL. The bitline BL is electrically connected to the drain region 86d through the bitline contact 78, by patterning.

FIG. 10 through FIG. 14 are sectional views illustrating another embodiment of a method of fabricating an EEPROM.

Referring to FIG. 10, a device isolation layer is conventionally formed on a semiconductor substrate 150 to define an active region. A gate insulator 154 is formed on the semiconductor substrate 150 where the active region is defined. The gate insulator 154 can be deposited through a chemical vapor deposition (CVD) process and can be made of thermal oxide formed on the active region. A hard mask layer 156 and an anti-reflective film 158 are formed on a substrate where the gate insulator 154 is formed. A photoresist pattern 160 is formed on the anti-reflective film 158. The photoresist pattern 160 includes a first opening D through which a tunnel insulation layer is to be formed. The first opening D can be formed in the minimum size defined by a photolithography.

To reduce an area of an active region exposed through the first opening D when viewed from the top of the fist photoresist pattern 160, the photoresist of the photoresist pattern 160 is flowed by annealing the substrate 150 where the photoresist pattern 160 is formed.

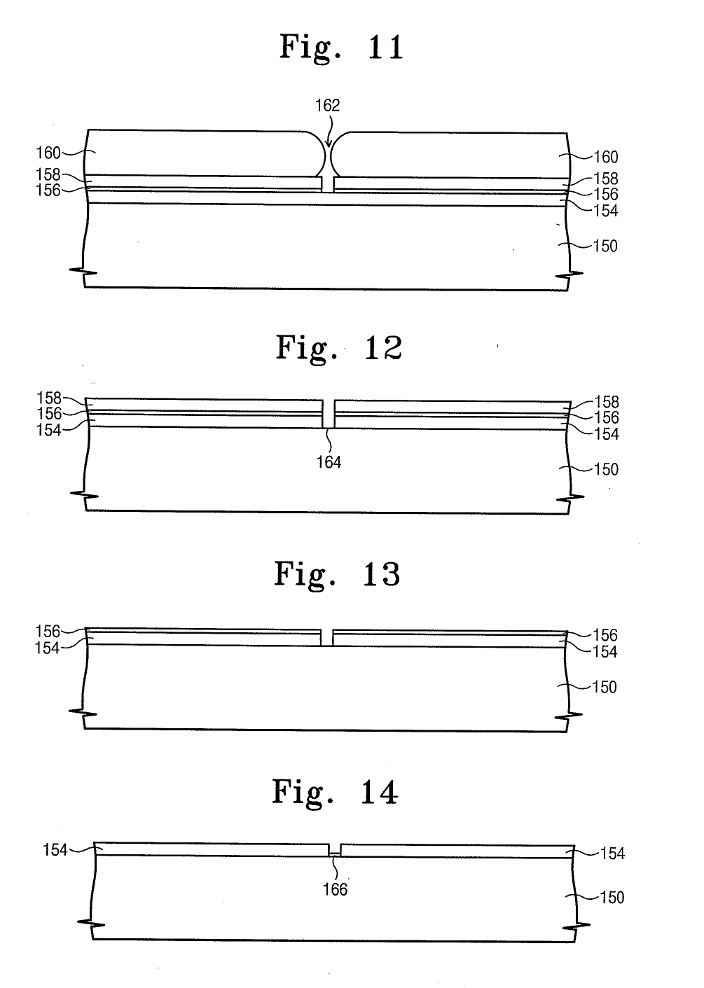

Referring to FIG. 11, the anti-reflective film 158 and the hard mask layer 156 are etched using the flowed photoresist pattern 160 as an etching mask, forming a second opening 162 to expose a portion of the gate insulator 154. Using the photoresist pattern 160 as an ion injection mask, impurities can be injected through the gate insulator 154 exposed by the second opening 162. Due to ion injection damage to the injected portions of the gate insulator 154, the impurity-injected portions of the gate insulator 154 have a higher etch rate than other portions of the gate insulator 154 in subsequent etching processes. Since the photoresist pattern 160 can be damaged while etching the anti-reflective film 158 and the hard mask layer 156, an ion injection process can be performed following the removal of the photoresist pattern 160.

Referring to FIG. 12, the photoresist pattern 160 is removed to expose the anti-reflective film 158. In the case where the anti-reflective film 158 is an inorganic anti-reflective film, it remains on the hard mask layer 156. The ion injection process through the gate insulator 154 can be performed following the removal of the photoresist pattern 160. Using the anti-reflective film 158 and the hard mask layer 156 as an etching mask, the gate insulator 154 is etched to form a tunneling opening 164. The removal of the gate insulator 154 can be done by an isotropic etching to prevent etching damage thereof. Even if the gate insulator 154 is isotropically etched, a lateral etching of the gate insulator 154 is suppressed due to the hard mask layer 156 to expose only an active region through the second opening 162. Since an etch rate of the gate insulator 154 varies with regions exposed and unexposed to ions, exposure of an active region through the second opening 162 is followed by exposure of an active region at the other portion. Thus, the tunneling opening 164 can be aligned with the second opening 162.

If the gate insulator 154 is etched using the flowed first photoresist pattern 160 as an etching mask, although impurities are not injected through the gate insulator, a tunneling opening 164 can be formed to have a smaller size than a size defined by a photolithography.

Referring to FIG. 13, in the case where the anti-reflective film 158 is an organic anti-reflective film, it is removed to expose the hard mask layer 156 during the removal of the photoresist pattern 160. The formation of the tunneling opening 164 can be done by etching the gate insulator 154 using the hard mask layer 156 as an etching mask.

Referring to FIG. 14, the hard mask layer 156 on a gate insulator 154 is removed. When the anti-reflective film 158 is on the hard mask layer 156, the anti-reflective film 158 is also removed to expose the gate insulator 154. A tunnel insulation layer 166 is formed on a portion of the substrate 150 exposed by the tunneling opening 164. The tunnel insulation layer 166 can be made of thermal oxide.

Although not shown in the figures, sensing lines SL and wordlines WL are conventionally formed to cross over the active region.

In the EEPROM of the present invention, the gate insulator defines the tunneling opening through which charges tunnel, and the opening defines sidewall in substantially a step or incline formed. Therefore, a tunnel insulation layer can be formed on an area smaller than the area defined by a photolithography. As a result, width of an active region and width of a wordline are decreased to reduce a unit cell size.

While aspects of the present invention have been particularly shown and described with reference to the above exemplary embodiments, it will be understood by those of ordinary skill in the art that various changes in form and details can be made without departing from the spirit and scope of the present disclosure and invention as defined by the following claims. It is intended, therefore, by the following claims to claim that which is literally described and all equivalents thereto, including all modifications and variations that fall within the scope of each claim.

What is claimed is:

1. An electrically erasable programmable read only memory (EEPROM) comprising:
a semiconductor substrate where a device isolation layer is formed to define an active region;
a gate insulator disposed on the active region and defining a tunneling opening exposing a portion of the active region;
a tunnel insulation layer disposed on the portion of the active region exposed by the tunneling opening;
a sensing line disposed on a first portion of the gate insulator and on the tunnel insulation layer, and on a first portion of the active region; and
a wordline disposed on a second portion of the gate insulator and on a second portion of the active region, and spaced apart from the sensing line,
wherein the gate insulator includes a side defining at least a portion of the tunneling opening and the side is inclined to make a bottom width of the tunneling opening smaller than a top width thereof.

2. The EEPROM of claim 1, further comprising:
a source region, a floating diffusion region, and a drain region formed in the active region,
wherein the wordline is disposed on the active region between the floating diffusion region and the drain region, and the sensing line is disposed on the active region between the source region and the floating diffusion region.

3. The EEPROM of claim 2, wherein the tunnel insulation layer is disposed on the floating diffusion region.

4. The EEPROM of claim 1, wherein the sensing line comprises a floating gate disposed on a first portion of the active region and a control gate electrode disposed on, and insulated from, the floating gate; and
wherein the wordline comprises a bottom wordline disposed on a second portion of the active region and a top wordline disposed on the bottom wordline, and wherein the bottom and top wordlines are electrically connected to each other.

5. The EEPROM of claim 1, further comprising:
a tunnel diffusion layer disposed in the active region and below the tunnel insulation layer.

6. A method of fabricating an electrically erasable programmable read only memory (EEPROM), the method comprising:
forming a gate insulator on an active region of a semiconductor substrate having a device isolation layer formed therein to define the active region;
forming a first photoresist pattern having a first opening exposing a first injection portion of the gate insulator;
injecting impurities into the gate insulator using the first photoresist pattern as an ion injection mask;
isotropically etching the gate insulator using the first photoresist pattern as an etching mask to form a tunneling opening having a stepped side;
removing the first photoresist pattern;
forming a tunnel insulation layer on a portion of the active region exposed by the tunneling opening; and
forming a sensing line on the tunnel insulation layer, on a first portion of the gate insulator, and on a first portion of the active region and forming a wordline on a second portion of the gate insulator and on a second portion of the active region, wherein the wordline is spaced apart from the sensing line.

7. The method of claim 6, further comprising before injecting the impurities:
flowing the first photoresist pattern to reduce a width of the first opening.

8. The method of claim 6, wherein forming the tunneling opening includes performing an isotropic wet etching of the gate insulator.

9. The method of claim 6, further comprising:
forming a second photoresist pattern having a second opening exposing a second injection portion of the gate insulator and the tunneling opening;
injecting impurities into the active region using the second photoresist pattern as an ion injection mask; and
removing the second photoresist pattern.

10. The method of claim 9, wherein forming the tunnel insulation layer is done after removing the second photoresist pattern.

11. The method of claim 9, further comprising:
injecting impurities into the active region using the wordline and the sensing line as an ion injection mask to form a source region, a floating diffusion region, and a drain region.

12. A method of fabricating an electrically erasable programmable read only memory (EEPROM), the method comprising:
sequentially forming a gate insulator, a hard mask layer, and anti-reflective film on an active region of a semiconductor substrate having a device isolation layer formed therein to define the active region;
forming a first photoresist pattern having a first opening exposing a portion of the anti-reflective film;
reflowing the first photoresist pattern to reduce a width of the first opening;
etching the anti-reflective film and the hard mask layer using the first photoresist pattern as an etching mask to form a second opening exposing the gate insulator;
removing the first photoresist pattern;
etching the gate insulator using the hard mask layer as an etching mask to form a tunneling opening;
removing the hard mask layer and the anti-reflective film; and
forming a tunnel insulation layer at the tunneling opening.

13. The method of claim 12, further comprising:
injecting impurities through the gate insulator exposed by the second opening.

14. The method of claim 13, wherein forming the tunneling opening includes:
etching a first portion of the gate insulator having been injected with the impurities at a first etch rate; and
etching other portions of the gate insulator covered with the hard mask at a second, slower etch rate.

15. The method of claim 12, wherein etching the gate insulator includes isotropic wet etching to form the tunneling opening.

16. The method of claim 12, wherein the anti-reflective film is an organic anti-reflective film that is removed with the photoresist pattern.

17. The method of claim 12, wherein the anti-reflective film is an inorganic anti-reflective film removed after forming the tunneling opening and before removing the hard mask.

18. The method of claim 12, further comprising:
forming a sensing line on the tunneling insulation layer and on a first portion of the gate insulator, and on a first portion of the active region and forming a wordline on a second portion of the active region and spaced apart from the sensing line.

19. The method of claim 18, further comprising:
injecting impurities into the active region using the wordline and the sensing line as an ion injection mask to form a source region, a floating diffusion region, and a drain region.

20. A method of fabricating an electrically erasable programmable read only memory (EEPROM), the method comprising:
forming a gate insulator on an active region of a semiconductor substrate having a device isolation layer formed therein to define the active region;
forming a first photoresist pattern having a first opening exposing a first injection portion of the gate insulator;
injecting impurities into the gate insulator using the first photoresist pattern as an ion injection mask;
isotropically etching the gate insulator using the first photoresist pattern as an etching mask to form a tunneling opening;
removing the first photoresist pattern; and
forming a tunnel insulation layer on a portion of the active region exposed by the tunneling opening, wherein the tunnel insulation layer covers an area not greater than that of the first opening.

21. The method of claim 20, further comprising:
forming a sensing line on the tunnel insulation layer, on a first portion of the gate insulator, and on a first portion of the active region and forming a wordline on a second portion of the gate insulator and on a second portion of the active region, wherein the wordline is spaced apart from the sensing line.
